(19) United States
(12) Patent Application Publication
(10) Pub. No.: US 2022/0344341 A1
(43) Pub. Date: Oct. 27, 2022

(54) SEMICONDUCTOR DEVICES HAVING AIR GAPS

(71) Applicant: SAMSUNG ELECTRONICS CO., LTD., Suwon-si (KR)

(72) Inventors: Huijung KIM, Seongnam-si (KR); Myeongdong LEE, Seoul (KR); Inwoo KIM, Suwon-si (KR); Sunghee HAN, Hwaseong-si (KR)

(21) Appl. No.: 17/558,855

(22) Filed: Dec. 22, 2021

(30) Foreign Application Priority Data
Apr. 22, 2021 (KR) 10-2021-0052312

(51) Int. Cl. H01L 27/108; H01L 21/768; H01L 23/528

(52) U.S. Cl. CPC H01L 27/10814; H01L 27/10823; H01L 27/10885; H01L 21/7682; H01L 21/76837; H01L 23/5283

(57) ABSTRACT

A semiconductor device that includes a substrate including an active region and a contact recess. A gate electrode is disposed in the substrate and extends in a first direction. A bit line structure intersects the gate electrode and extends in a second direction intersecting the first direction. The bit line structure includes a direct contact disposed in the contact recess. A buried contact is disposed on the substrate and is electrically connected to the active region. A spacer structure is disposed between the bit line structure and the buried contact. The spacer structure includes a buried spacer disposed on a lateral side surface of the direct contact, and an air gap disposed on the buried spacer. The air gap exposes a lateral side surface of the bit line structure.

### CROSS-REFERENCE TO THE RELATED APPLICATION

This application claims priority under 35 U.S.C. § 119 to Korean Patent Application No. 10-2021-0052312, filed on Apr. 22, 2021 in the Korean Intellectual Property Office, the disclosure of which is incorporated by reference in its entirety herein.

### 1. TECHNICAL FIELD

Embodiments of the present inventive concept relate to a semiconductor device having an air gap.

### 2. DISCUSSION OF RELATED ART

The sizes of semiconductor devices are being scaled down in response to an increasing demand for high integration and miniaturization of semiconductor devices. Accordingly, a semiconductor memory device used in an electronic device may have a high integration and design rules for the constituent elements of the semiconductor memory device may be reduced. While the size of the semiconductor device may be reduced, the reliability of the semiconductor device should be maintained.

### SUMMARY

Embodiments of the present inventive concept provide a semiconductor device including a spacer structure having an air gap.

According to an embodiment of the present inventive concept, a semiconductor device may include a substrate including an active region and a contact recess. A gate electrode is disposed in the substrate and extends in a first direction. A bit line structure intersects the gate electrode and extends in a second direction intersecting the first direction. The bit line structure includes a direct contact disposed in the contact recess. A buried contact is disposed on the substrate and is electrically connected to the active region. A spacer structure is disposed between the bit line structure and the buried contact. The spacer structure includes a buried spacer disposed on a lateral side surface of the direct contact, and an air gap disposed on the buried spacer. The air gap exposes a lateral side surface of the bit line structure.

According to an embodiment of the present inventive concept, a semiconductor device may include a substrate including an active region and a contact recess. A gate electrode is disposed in the substrate and extends in a first direction. A first bit line structure and a second bit line structure intersect the gate electrode and extend in a second direction intersecting the first direction. The first bit line structure includes a direct contact disposed in the contact recess. A buried contact is electrically connected to the active region and is disposed between the first bit line structure and the second bit line structure. A landing pad is disposed on the buried contact. A first spacer structure is disposed between the first bit line structure and the buried contact. The first spacer structure includes a buried spacer disposed on a lateral side surface of the direct contact, and a first air gap disposed on the buried spacer. A second spacer structure is disposed between the second bit line structure and the buried contact. The second spacer structure includes a second air gap disposed on the substrate. The first air gap exposes a lateral side surface of at least one of the first bit line structure and the buried contact.

According to an embodiment of the present inventive concept, a semiconductor device a substrate may include an active region and a contact recess. A gate electrode is disposed in the substrate and extends in a first direction. A first bit line structure and a second bit line structure intersect the gate electrode and extend in a second direction intersecting the first direction. The first bit line structure includes a direct contact disposed in the contact recess. A buried contact electrically connects to the active region and is disposed between the first bit line structure and the second bit line structure. A landing pad is disposed on the buried contact. An insulating structure directly contacts the landing pad and the first bit line structure. A first spacer structure is disposed between the first bit line structure and the buried contact. The first spacer structure includes a buried spacer disposed on a lateral side surface of the direct contact, and a first air gap disposed on the buried spacer. A second spacer structure is disposed between the second bit line structure and the buried contact. The second spacer structure includes a second air gap on the substrate. A capacitor structure is disposed on the landing pad. The first air gap exposes the insulating structure, the first bit line structure and the buried contact, and the second air gap exposes a lateral side surface of the second bit line structure.

### BRIEF DESCRIPTION OF THE DRAWINGS

The above and other objects, features, and advantages of the present inventive concept will become more apparent to those skilled in the art upon consideration of the following detailed description with reference to the accompanying drawings.

FIG. 1 is a plan view of a semiconductor device according to an embodiment of the present inventive concept.

FIG. 2 are cross-sectional views of the semiconductor device taken along lines I-I′ and II-II′ of FIG. 1 according to an embodiment of the present inventive concept.

FIG. 3 is an enlarged view of the semiconductor device shown in FIG. 2 according to an embodiment of the present inventive concept.

FIGS. 4, 6, 8, 10, 12, 14, 16, 18, 20 are plan views illustrating a method of manufacturing a semiconductor device according to embodiments of the present inventive concepts.

FIGS. 5, 7, 9, 11, 13, 15, 17, 19 and 21 are cross-sectional views taken along lines I-I′ and II-II′ of FIGS. 4, 6, 8, 10, 12, 14, 16, 18, 20, respectively, illustrating a method of manufacturing a semiconductor device according to embodiments of the present inventive concepts.

FIGS. 22 to 28 are enlarged cross-sectional views illustrating a method of manufacturing a semiconductor device according to embodiments of the present inventive concepts;

FIGS. 29 to 31 are vertical cross-sectional views illustrating in process order a method of manufacturing a semiconductor device according to embodiments of the present inventive concept.

FIGS. 32 to 35 are enlarged cross-sectional views of semiconductor devices according to embodiments of the present inventive concept.

### DETAILED DESCRIPTION OF EMBODIMENTS

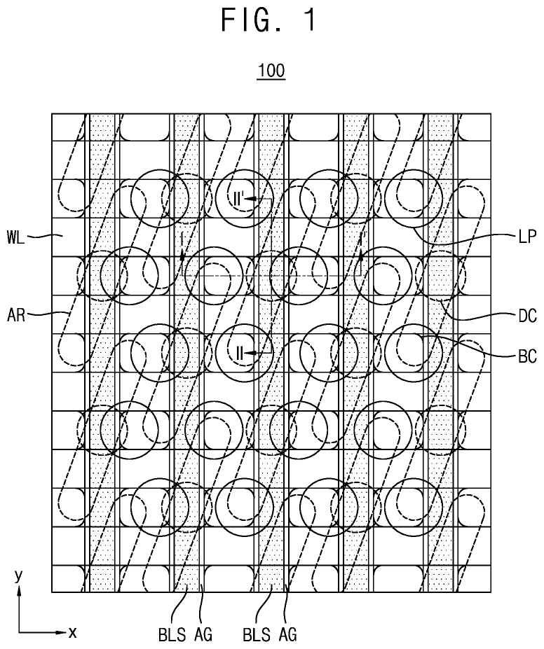

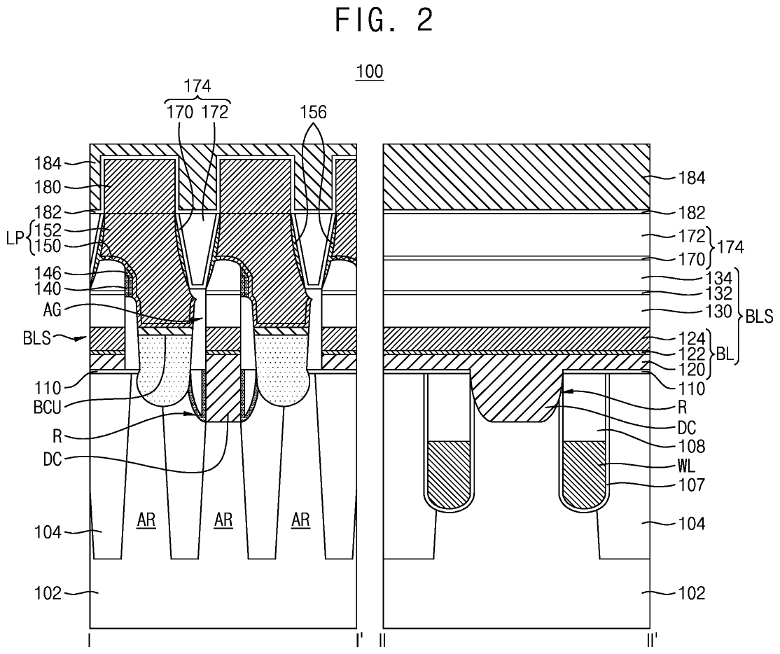

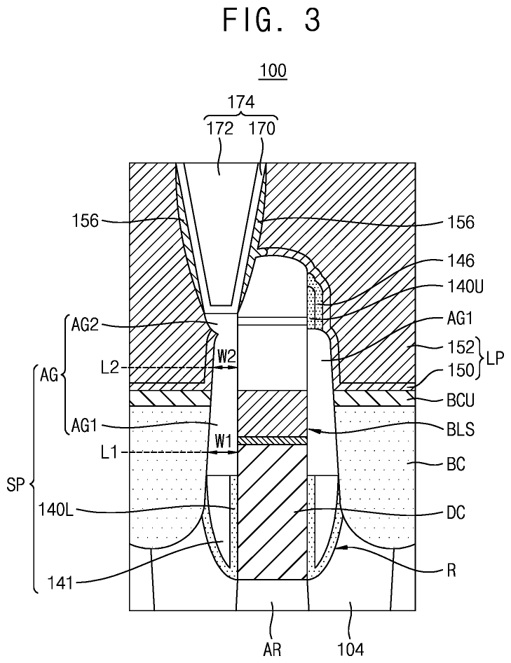

FIG. 1 is a layout of a semiconductor device according to an embodiment of the present inventive concept. FIG. 2 is vertical cross-sectional views of the semiconductor device taken along lines I-I′ and II-II′ in FIG. 1. FIG. 3 is an enlarged view of the semiconductor device shown in FIG. 2.

Referring to FIGS. 1 to 3, a semiconductor device 100 may include a substrate 102, a gate electrode WL, a bit line structure BLS, a spacer structure SP, a buried contact BC, a landing pad LP, an insulating structure 174, a lower electrode 180, a capacitor dielectric layer 182, and an upper electrode 184.

In an embodiment, the substrate 102 may include a semiconductor material. For example, the substrate 102 may be a silicon substrate, a germanium substrate, a silicon germanium substrate, or a silicon-on-insulator (SOI) substrate. However, embodiments of the present inventive concept are not limited thereto.

The substrate 102 may include an active region AR and an element isolation layer 104. The element isolation layer 104 may be an insulating layer extending downwards from an upper surface of the substrate 102 (e.g., in a thickness direction of the substrate 102), and may define active regions AR. For example, the active regions AR may correspond to portions of the upper surface of the substrate 102 surrounded by the element isolation layer 104, respectively. When viewed in a plan view (e.g., in a plane defined in the X and Y directions), the active regions AR may have a bar shape having a shorter axis and a longer axis, and may be spaced apart from one another.

When viewed in a plan view (e.g., in a plane defined in the X and Y directions), gate electrodes WL may extend longitudinally in the X direction while being spaced apart from one another in the Y direction. In the specification, the X direction and the Y direction may be referred to as a first direction (e.g., a horizontal direction) that extends parallel to the x axis and a second direction (e.g., a horizontal direction) that extends parallel to the y axis, respectively. In addition, the gate electrodes W L may intersect the active regions AR. For example, in an embodiment, two gate electrodes WL may intersect one active region AR. However, embodiments of the present inventive concept are not limited thereto. When viewed in a cross-sectional view, the gate electrodes W L may be buried in the substrate 102. For example, each gate electrode WL may be disposed within a trench formed in the substrate 102. The semiconductor device 100 may further include a gate dielectric layer 107 and a gate capping layer 108 which are disposed in the trench. The gate dielectric layer 107 may be conformally formed at an inner wall of the trench. The gate electrode WL may be disposed at a lower portion of the trench, and the gate capping layer 108 may be disposed on the gate electrode WL. For example, a lower surface of the gate capping layer 108 may directly contact an upper surface of the gate electrode WL. In an embodiment, an upper surface of the gate capping layer 108 may be coplanar with upper surfaces of the element isolation layer 104 and an area separation layer.

The semiconductor device 100 may further include a buffer layer 110 covering the upper surfaces of the element isolation layer 104 and the gate capping layer 108. In an embodiment, the buffer layer 110 may include silicon nitride. However, embodiments of the present inventive concept are not limited thereto.

When viewed in a plan view, bit line structures BLS may extend longitudinally in the Y direction while being spaced apart from one another in the X direction. The bit line structures BLS may include a bit line BL, a first capping layer 130, an insulating liner 132 and a second capping layer 134 which are sequentially stacked on the buffer layer 110.

The bit line BL may include a first conductive layer 120, a second conductive layer 122 and a third conductive layer 124 which are sequentially stacked on the buffer layer 110. The first conductive layer 120 may include a direct contact DC that directly contacts the active region AR while extending through the buffer layer 110. For example, the direct contact DC may be disposed in a contact recess R formed at the upper surface of the substrate 102. In an embodiment, when viewed in a plan view (e.g., in a plane defined in the X and Y directions), the direct contact DC may be disposed at a central portion of the active region AR. The direct contact DC may be a portion of the first conductive layer 120. The direct contact DC may electrically connect the active region AR to the bit line structure BLS. In an embodiment, the first conductive layer 120 may include polysilicon, and each of the second conductive layer 122 and the third conductive layer 124 may include TiN, TiSiN, W, tungsten silicide, or a combination thereof. However, embodiments of the present inventive concept are not limited thereto.

The first capping layer 130, the insulating liner 132 and the second capping layer 134 may be sequentially stacked on the bit line BL. For example, a lower surface of the first capping layer 130 may directly contact an upper surface of the third conductive layer 124. The first capping layer 130, the insulating liner 132 and the second capping layer 134 may extend longitudinally in the Y direction on the bit line BL. In an embodiment, the first capping layer 130, the insulating liner 132 and the second capping layer 134 may include silicon nitride. However, embodiments of the present inventive concept are not limited thereto. In an embodiment, the first capping layer 130, the insulating liner 132 and the second capping layer 134 may be integrally formed. The first capping layer 130, the insulating liner 132 and the second capping layer 134 may be commonly referred to as a capping layer.

Spacer structures SP may be disposed on opposite lateral side surfaces of the bit lines BL, respectively, and may extend longitudinally in the Y direction. In addition, the spacer structure SP may extend into the contact recess R of the substrate 102 at a portion thereof overlapping with the direct contact DC in a vertical direction, and may cover lateral side surfaces of the direct contact DC.

The spacer structure SP may include an inner spacer 140, a buried spacer 141, an upper spacer 146, and an air gap AG. The inner spacer 140 may contact lateral side surfaces of the bit line structure BLS, and may include an inner lower spacer 140L and an inner upper spacer 140U. For example, the inner lower spacer 140L may be disposed along an inner wall of the contact recess R and the lateral side surfaces of the direct contact DC. In an embodiment, the inner lower spacer 140L may partially cover the lateral side surfaces of the direct contact DC and, as such, the lateral side surfaces of the direct contact DC may be partially exposed. For example, as shown in FIG. 3, an upper portion of the lateral side surfaces of the direct contact DC may be partially exposed. The inner upper spacer 140U may cover an upper lateral side surface of the bit line structure BLS. For example, the inner upper spacer 140U may partially cover lateral side surfaces of the first capping layer 130, the insulating liner 132 and the second capping layer 134. For example, as shown in the embodiment of FIG. 3, the inner upper spacer 140U may partially cover one lateral side surface of the first capping layer 130 and the second capping layer 134 and may completely cover one lateral side surface of the insulating liner 132. The inner upper spacer 140U may extend longitudinally in the Y direction.

The buried spacer 141 may be disposed within the contact recess R. For example, the buried spacer 141 may be formed on (e.g., disposed directly on) the inner lower spacer 140L, and may fill the contact recess R. An upper surface of the buried spacer 141 may be coplanar with an upper surface of the inner lower spacer 140L. In an embodiment, the buried spacer 141 may include silicon oxide, silicon nitride, silicon oxynitride, or a combination thereof. However, embodiments of the present inventive concept are not limited thereto.

The upper spacer 146 may be disposed on an upper lateral side surface of the bit line structure BLS. For example, the upper spacer 146 may cover an upper surface and a lateral side surface of the inner upper spacer 140U, and may directly contact the second capping layer 134. In an embodiment, the upper spacer 146 may include silicon nitride. However, embodiments of the present inventive concept are not limited thereto. For example, in some embodiments, the inner upper spacer 140U and/or the upper spacer 146 may be omitted.

The air gap AG may extend longitudinally from a lateral side surface of the bit line structure BLS in the Y direction, and may include a lower air gap AG1 and an upper air gap AG2. When viewed in a longitudinal cross-sectional view, the air gap AG may have a concave portion, and the portion of the air gap AG below the concave portion may be referred to as the lower air gap AG1, and the portion of the air gap AG above the concave portion may be referred to as the upper air gap AG2. The lower air gap AG1 may expose the buried contact BC and the bit line structure BLS. For example, the lower air gap AG1 may partially expose lateral side surfaces of the buried contact BC and the bit line structure BLS. The lower air gap AG1 may be defined by the buried spacer 141, the inner lower spacer 140L, the buried contact BC, the bit line structure BLS, the landing pad LP, and a silicide pattern BCU. Portions of the buried contact BC and the direct contact DC covered by the inner lower spacer 140L may not be exposed to the lower air gap AG1. In an embodiment, the lower air gap AG1 may be formed by completely removing spacer materials among the bit line structure BLS, the landing pad LP and the buried contact BC and may be a void that is filled with air. There may be no intermediate material among the bit line structure BLS, the landing pad LP and the buried contact BC. For example, at a first vertical level L1 between an upper surface of the buried spacer 141 and the buried contact BC (e.g., in a thickness direction of the substrate 102), the horizontal distance between the buried contact BC and the bit line structure BLS may be equal to a horizontal width W1 of the lower air gap AG1. In addition, at a second vertical level L2 between a lower surface of the landing pad LP and the upper air gap AG2 (e.g., in a thickness direction of the substrate 102), the horizontal distance between the landing pad LP and the bit line structure BLS may be equal to a horizontal width W2 of the lower air gap AG1. Since there is no intermediate material between the bit line structure BLS and the buried contact BC, the horizontal width of the lower air gap AG1 may be maximized and, as such, parasitic capacitance between the buried contact BC and the bit line structure BLS may be reduced.

The upper air gap AG2 may communicate with the lower air gap AG1, and may be defined by the landing pad LP, the insulating structure 174 and the bit line structure BLS. For example, the upper air gap AG2 may be disposed between the lower air gap AG1 and the insulating structure 174 (e.g., in a thickness direction of the substrate 102). A portion of the landing pad LP between the upper air gap AG2 and the lower air gap AG1 may protrude horizontally toward the bit line structure BLS.

The buried contact BC may be disposed among the bit line structures BLS and may be spaced apart from the bit line structures BLS by the spacer structure SP. An upper surface of the buried contact BC may be disposed at a lower level than an upper surface of the bit line structure BLS, and may extend into the substrate 102. For example, a lower end of the buried contact BC may be disposed at a lower level than the upper surface of the substrate 102, and may directly contact the active region AR for electrical connection to the active region AR. In an embodiment, the semiconductor device 100 may further include fence insulating layers alternately disposed with buried contacts BC in the Y direction when viewed in a plan view. The fence insulating layers may overlap with the gate electrodes WL. The semiconductor device 100 may further include the silicide pattern BCU which directly contacts the landing pad LP and the buried contact BC. In an embodiment, the silicide pattern BCU may be formed by silicidizing the upper surface of the buried contact BC. However, embodiments of the present inventive concept are not limited thereto. For example, in an embodiment, the silicide pattern BCU may be omitted. In an embodiment, the buried contact BC may include polysilicon, and the silicide pattern BCU may include metal silicide. However, embodiments of the present inventive concept are not limited thereto.

The landing pad LP may be disposed on the buried contact BC, and may directly contact the silicide pattern BCU. For example, in an embodiment, the lower surface of the landing pad LP may be disposed at a lower level than an upper surface of the second capping layer 134, and may correspond to the buried contact BC. The landing pad LP may be partially exposed by the air gap AG. An upper surface of the landing pad LP may be disposed at a higher level than the second capping layer 134. The landing pad LP may be electrically connected to the active region AR via the buried contact BC. The landing pad LP may include a barrier pattern 150, and a conductive pattern 152 disposed on the barrier pattern 150. In an embodiment, the barrier pattern 150 may be conformally disposed on the bit line structures BLS and the buried contacts BC, and the conductive pattern 152 may cover the barrier pattern 150.

The insulating structures 174 may be disposed among the landing pads LP, and may electrically insulate the landing pads LP from one another. In an embodiment, the insulating structures 174 may directly contact the landing pads LP. An upper surface of the insulating structures 174 may be coplanar with the upper surface of the landing pad LP (e.g., in a thickness direction of the substrate 102). The insulating structure 174 may extend downwards from the upper surface of the landing pad LP and may directly contact the bit line structure BLS. The insulating structure 174 may include a lower insulating layer 170, and an upper insulating layer 172 disposed on the lower insulating layer 170. The lower insulating layer 170 may be conformally disposed along a lower surface and lateral side surfaces of the insulating structure 174, and may directly contact the bit line structure BLS. In addition, the lower insulating layer 170 may define an upper limit of the upper air gap AG2. The upper insulating layer 172 may fill a space inside an inner wall of the lower insulating layer 170. In an embodiment, the lower insulating layer 170 and the upper insulating layer 172 may include silicon oxide, silicon nitride, silicon oxynitride, or a combination thereof. However, embodiments of the present inventive concept are not limited thereto.

The semiconductor device 100 may further include an insulating pattern 156 disposed between the insulating structure 174 and the landing pad LP. In an embodiment, the insulating pattern 156 may include silicon nitride. However, embodiments of the present inventive concept are not limited thereto. For example, in an embodiment, the insulating pattern 156 may be omitted.

A capacitor structure of the semiconductor device 100 may be disposed on a corresponding one of the landing pads LP. The capacitor structure may be constituted by the lower electrode 180, the capacitor dielectric layer 182, and the upper electrode 184. The lower electrode 180 may be disposed to directly contact an upper surface of the corresponding landing pad LP, and the capacitor dielectric layer 182 may be conformally disposed along the insulating structure 174 and the lower electrode 180. The upper electrode 184 may be disposed directly on the capacitor dielectric layer 182.

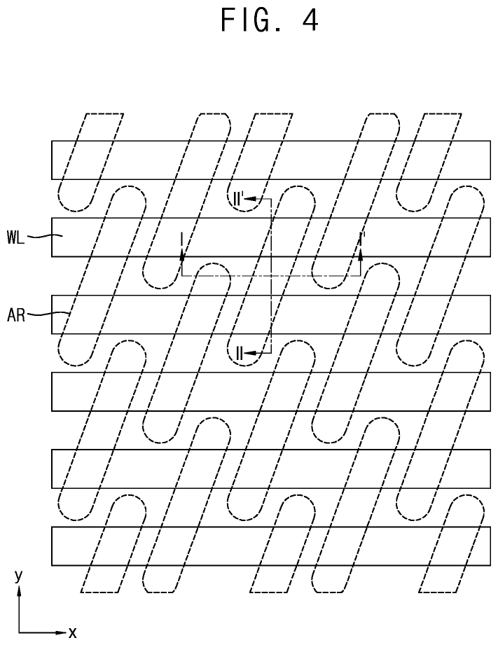

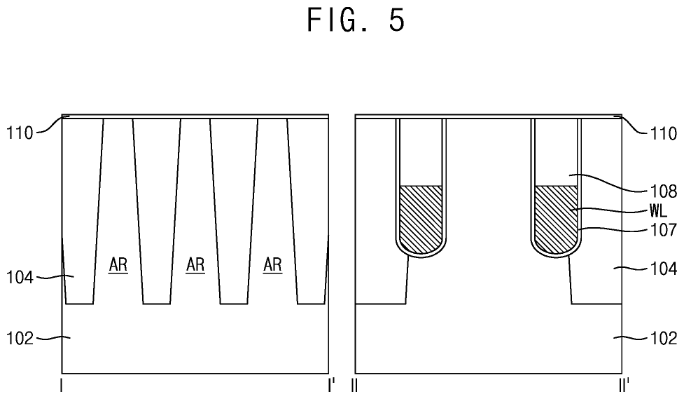

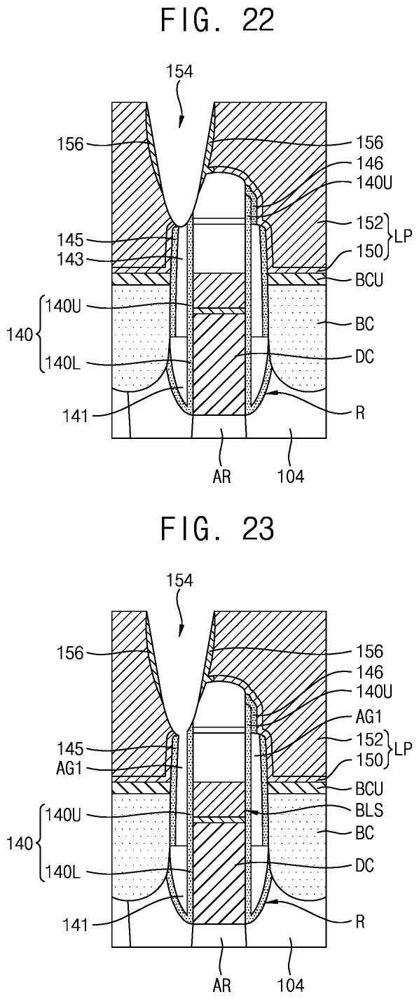

FIGS. 4 to 28 are plan views and vertical cross-sectional views illustrating in process order of a method of manufacturing a semiconductor device according to an embodiment of the present inventive concept. FIGS. 4, 6, 8, 10, 12, 14, 16, 18 and 20 are plan views. FIGS. 5, 7, 9, 11, 13, 15, 17, 19 and 21 are cross-sectional views taken along lines I-I′ and II-II′ in FIGS. 4, 6, 8, 10, 12, 14, 16, 18 and 20, respectively. FIGS. 22 to 28 are enlarged views of the cross-sectional views taken along line 1-4′, respectively.

Referring to FIGS. 4 and 5, an element isolation layer 104 and an area separation layer may be formed on a substrate 102. The element isolation layer 104 may be formed by forming a trench on an upper surface of the substrate 102, and filling the trench with an insulating material. The element isolation layer 104 may define active regions AR. For example, the active regions AR may correspond to portions of the upper surface of the substrate 102 surrounded by the element isolation layer 104, respectively. When viewed in a plan view (e.g., in a plane defined by the X and Y directions), the active regions AR may have a bar shape having a shorter axis and a longer axis, and may be spaced apart from one another. In an embodiment, the element isolation layer 104 may include silicon oxide, silicon nitride, silicon oxynitride, or a combination thereof. The element isolation layer 104 may be formed by a single layer or multiple layers.

Gate electrodes WL may be formed in a cell area, to intersect the active regions AR. For example, in an embodiment, the gate electrodes WL may be formed by forming trenches extending longitudinally in an X direction on the upper surface of the substrate 102, forming a gate dielectric layer 107 covering an inner wall of the trench, forming a conductive material at a lower portion of the trench, and forming a gate capping layer 108 at an upper portion of the trench. The gate electrodes WL may be spaced apart from each other in the Y direction. An upper surface of the gate capping layer 108 may be coplanar with the upper surface of the substrate 102 and upper surfaces of the element isolation layer 104 and the area separation layer.

In an embodiment, the gate electrodes WL may include Ti, TiN, Ta, TaN, W, WN, TiSiN, WSiN, or a combination thereof. The gate dielectric layer 107 may include silicon oxide, silicon nitride, silicon oxynitride, high-k dielectrics, or a combination thereof. The gate capping layer 108 may include silicon oxide, silicon nitride, silicon oxynitride, or a combination thereof. However, embodiments of the present inventive concept are not limited thereto.

In an embodiment, after formation of the gate electrodes WL, a source region and a drain region may be formed by implanting impurity ions in portions of the substrate 102 corresponding to the active regions AR at opposite sides of each gate electrode WL. However, embodiments of the present inventive concept are not limited thereto. For example, in an embodiment, an impurity ion implantation process for formation of the source region and the drain region may be performed before formation of the gate electrodes WL.

A buffer layer 110 may be formed to cover the element isolation layer 104, the active regions AR and the gate capping layer 108. In an embodiment, the buffer layer 110 may include silicon oxide, silicon nitride, silicon oxynitride, high-k dielectrics, or a combination thereof.

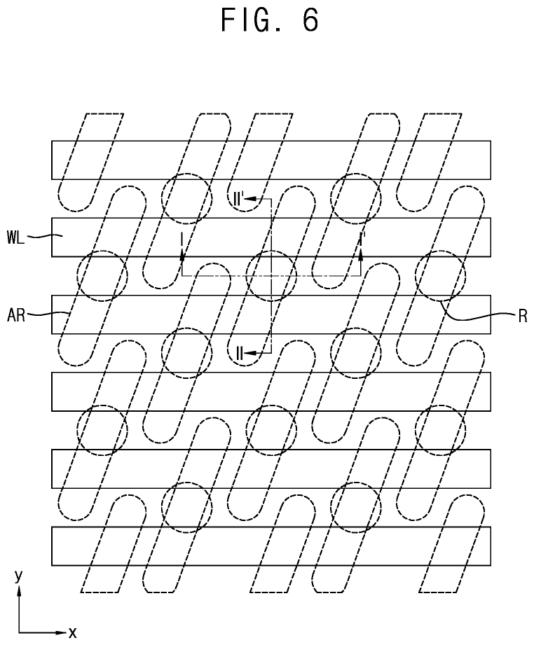

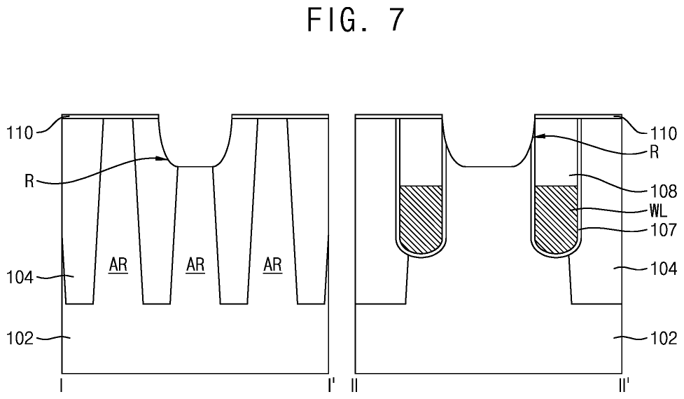

Referring to FIGS. 6 and 7, a contact recess R may be formed on the upper surface of the substrate 102. In an embodiment, the formation of the contact recess R may be performed by an anisotropic etching process. The element isolation layer 104 and the buffer layer 110 may be etched, and an upper surface of the active region AR may be exposed by the contact recess R. When viewed in a plan view (e.g., in a plane defined in the X and Y directions), the contact recess R may be formed at a central portion of the active region AR, and, for example, may be formed at the source region of the active region AR. However, embodiments of the present inventive concept are not limited thereto.

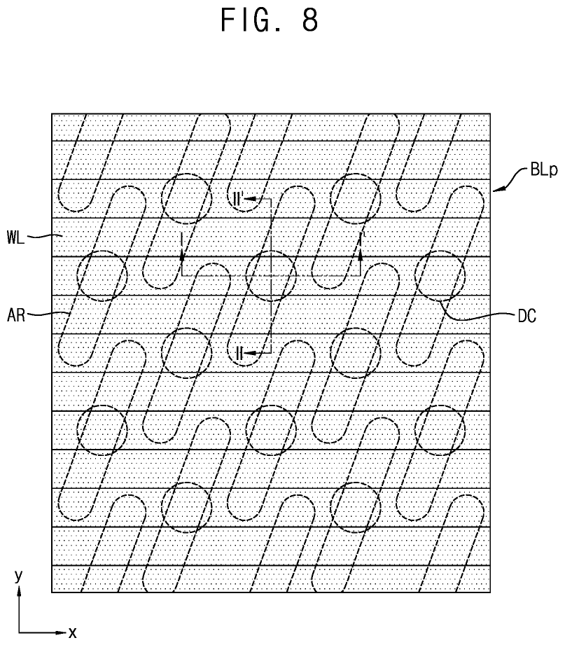

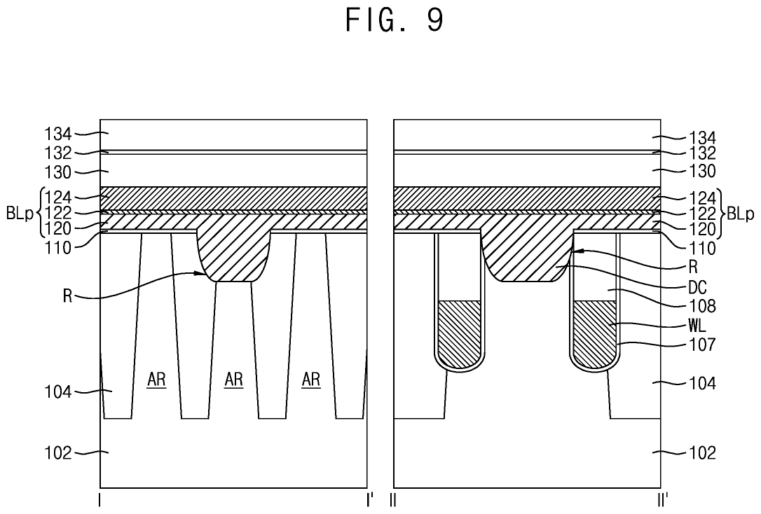

Referring to FIGS. 8 and 9, a first conductive layer 120, a second conductive layer 122, a third conductive layer 124, a first capping layer 130, an insulating liner 132, and a second capping layer 134 may be formed. The first conductive layer 120 may fill the contact recess R, and may cover the buffer layer 110. In an embodiment, the first conductive layer 120 may be formed by depositing a conductive material on the contact recess R and the buffer layer 110, and performing a planarization process. A portion of the first conductive layer 120 filling the contact recess R may be referred to as a direct contact DC. For example, the direct contact DC may be buried in the substrate 102, and may contact the element isolation layer 104 and the active region AR. In an embodiment, the first conductive layer 120 may include polysilicon. However, embodiments of the present inventive concept are not limited thereto.

The second conductive layer 122, the third conductive layer 124, the first capping layer 130, the insulating liner 132, and the second capping layer 134 may be sequentially stacked on the first conductive layer 120. The first conductive layer 120, the second conductive layer 122 and the third conductive layer 124 may form a bit line material layer BLp. In the specification, the first capping layer 130, the insulating liner 132 and the second capping layer 134 may be commonly referred to as a capping layer. In an embodiment, each of the second conductive layer 122 and the third conductive layer 124 may include TiN, TiSiN, W, tungsten silicide, or a combination thereof. The first capping layer 130, the insulating liner 132 and the second capping layer 134 may include silicon oxide, silicon nitride, silicon oxynitride, or a combination thereof. However, embodiments of the present inventive concept are not limited thereto.

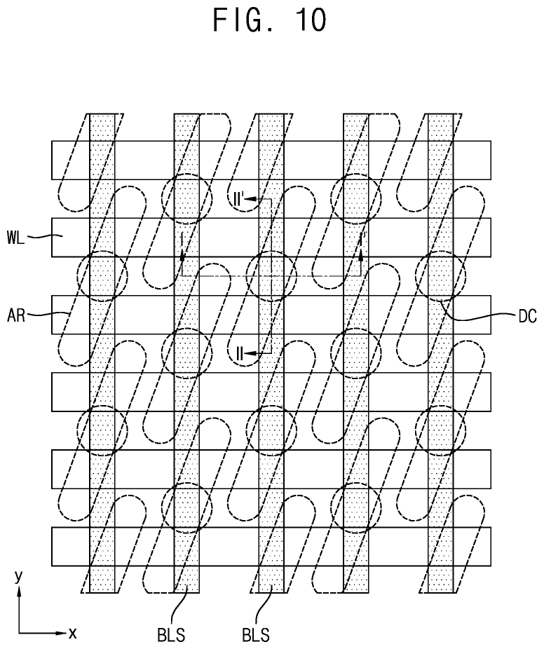

Referring to FIGS. 10 and 11, the first conductive layer 120, the second conductive layer 122, the third conductive layer 124, the first capping layer 130, the insulating liner 132, and the second capping layer 134 may be etched. The etching process may be an anisotropic etching process. In the etching process, the direct contact DC may be partially etched, and lateral side surfaces of the etched direct contact DC may be exposed. The etched first conductive layer 120, the etched second conductive layer 122 and the etched third conductive layer 124 may constitute a bit line BL. When viewed in a plan view (e.g., in a plane defined in the X and Y directions), the bit lines BL may have a bar shape extending longitudinally in the Y direction. In addition, the first capping layer 130, the insulating liner 132 and the second capping layer 134 may extend longitudinally on the bit line BL in the Y direction. The bit line BL, the first capping layer 130, the insulating liner 132, and the second capping layer 134 may constitute a bit line structure BLS.

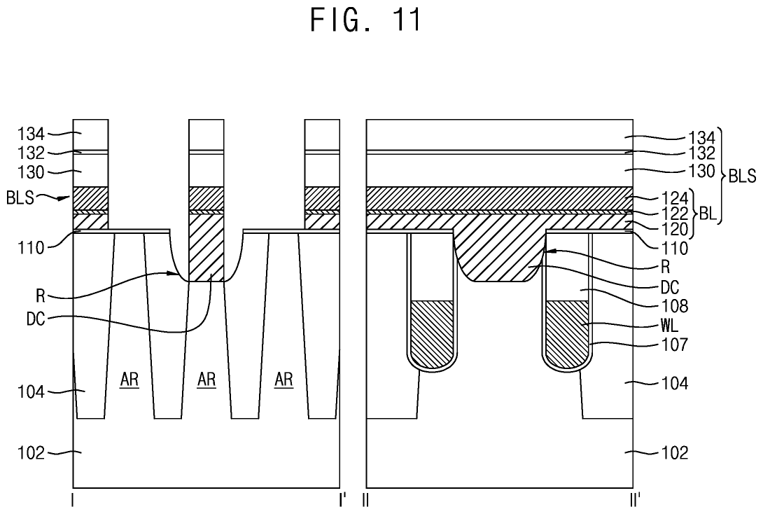

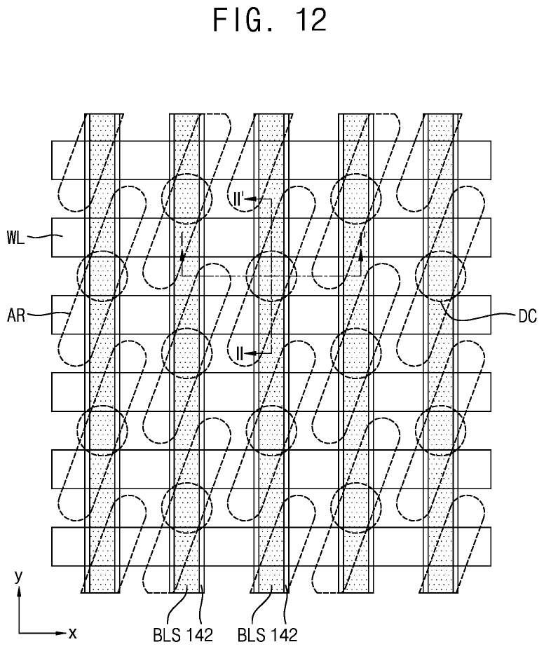

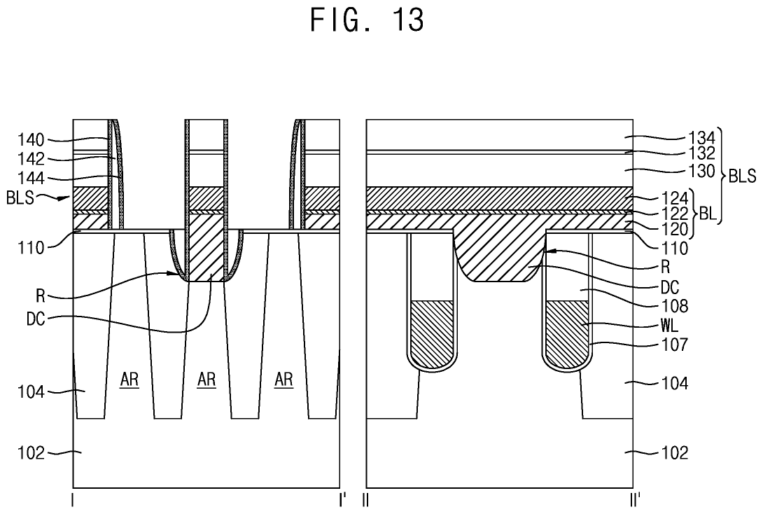

Referring to FIGS. 12 and 13, an inner spacer 140 and a buried spacer 141 may be formed on a lateral side surface of the bit line structure BLS. In an embodiment, the inner spacer 140 and the buried spacer 141 may be formed by conformally depositing an inner spacer material layer on the resultant structure of FIG. 11, depositing a buried spacer material layer on the inner spacer material layer for the inner spacer 140, and performing an anisotropic etching process such that an upper surface of the buffer layer 110 is exposed. The inner spacer 140 may be conformally formed along the lateral side surfaces of the bit line structure BIS and an inner wall of the contact recess R. The buried spacer 141 may be formed within the contact recess R. For example, the buried spacer 141 may be formed on the inner spacer 140, and may fill the contact recess R. In an embodiment, an upper surface of the buried spacer 141 may be coplanar with the upper surface of the buffer layer 110. The inner spacer 140 may extend longitudinally along the bit line structure BLS in the Y direction, and buried spacers 141 may be disposed in the contact recesses R, respectively.

Thereafter, a sacrificial spacer 142 and an outer spacer 144 may be formed. In an embodiment, the sacrificial spacer 142 and the outer spacer 144 may be formed by sequentially stacking a spacer material layer on the inner spacer 140, and performing an anisotropic etching process such that the upper surface of the buffer layer 110 is exposed. For example, the sacrificial spacer 142 may be formed on a lateral side surface of the inner spacer 140, and a lower surface of the sacrificial spacer 142 may directly contact the upper surface of the buried spacer 141. The outer spacer 144 may be formed on a lateral side surface of the sacrificial spacer 142, and a lower surface of the outer spacer 144 may directly contact the buried spacer 141. The sacrificial spacer 142 and the outer spacer 144 may extend longitudinally along the bit line structure BLS in the Y direction.

The sacrificial spacer 142 may include a material having etch selectivity with respect to the inner spacer 140 and the buried spacer 141. In an embodiment, the sacrificial spacer 142 may include silicon oxide, and the inner spacer 140 and the buried spacer 141 may include silicon nitride, silicon oxynitride, or a combination thereof. In an embodiment, at least one of the inner spacer 140 and the buried spacer 141 may include SiC, SiOC, SiOCN, or a combination thereof. The buried spacer 141 may include a material having etch selectivity with respect to the sacrificial spacer 142. For example, the buried spacer 141 may include silicon oxide, silicon nitride, silicon oxynitride, or a combination thereof. However, embodiments of the present inventive concept are not limited thereto.

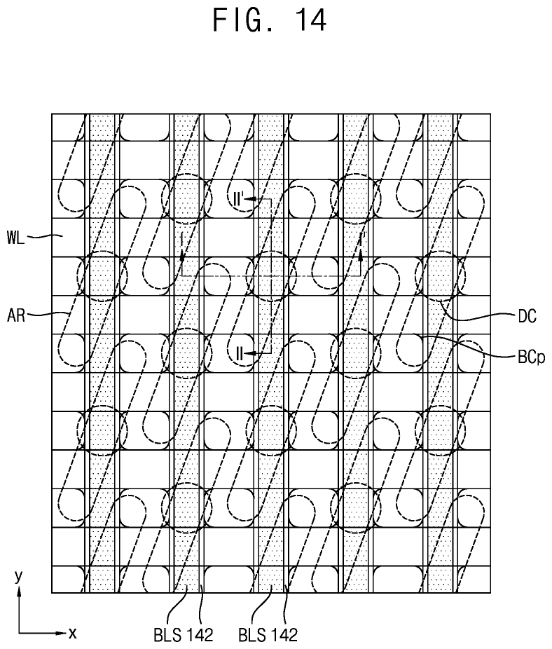

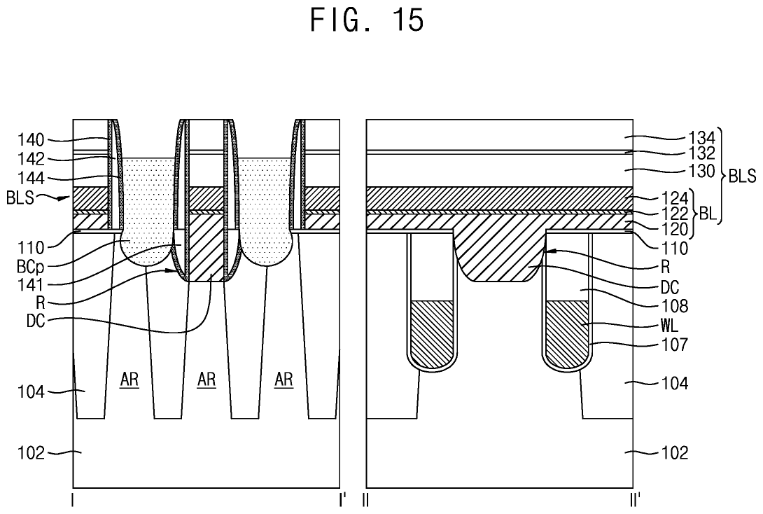

Referring to FIGS. 14 and 15, preliminary contact layers BCp may be formed among bit line structures BLS. Sacrificial layers 160 (FIG. 25) and fence insulating layers may be formed before formation of the preliminary contact layer BCp. For example, in an embodiment, the preliminary contact layers BCp may be formed by filling the sacrificial layer 160 extending longitudinally in the Y direction among the bit line structures BLS, forming the fence insulating layers in regions where the sacrificial layer 160 intersects a gate line, removing the sacrificial layer 160, and filling a conductive layer. In an embodiment, the formation of the preliminary contact layer BCp may further include partially etching the conductive layer by an etch-back process. For example, an upper surface of the preliminary contact layer BCp may be disposed at a lower level than an upper surface of the bit line structure BLS. The preliminary contact layers BCp and the fence insulating layers may be alternately disposed in the Y direction among the bit line structures BLS. The preliminary contact layers BCp may extend into the substrate 102. For example, the preliminary contact layers BCp may extend through the buffer layer 110 and the inner spacer 140 on the inner wall of the contact recess R, and may directly contact the active regions AR. In an embodiment, the preliminary contact layer BCp may include polysilicon. However, embodiments of the present inventive concept are not limited thereto.

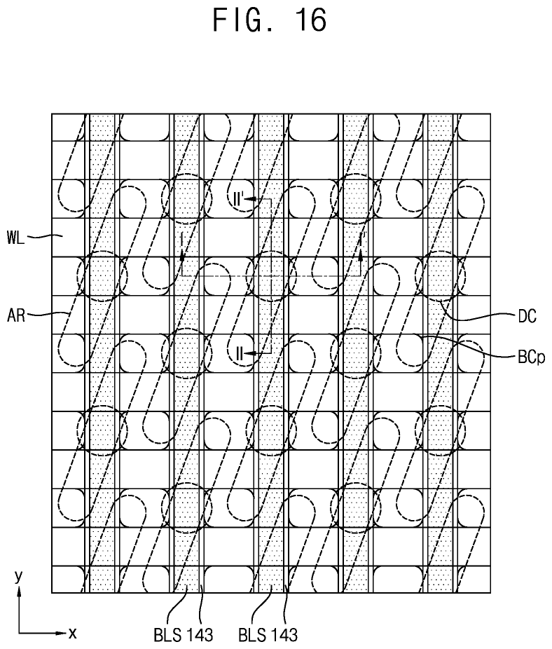

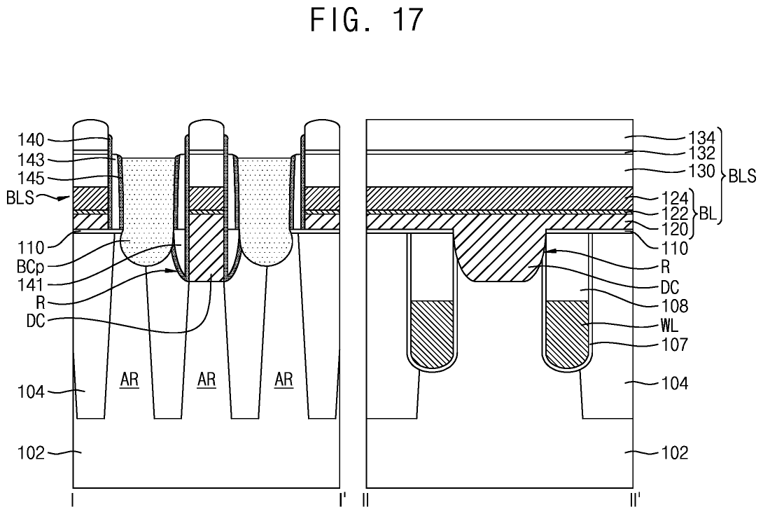

Referring to FIGS. 16 and 17, the sacrificial spacer 142 and the outer spacer 144 may be partially etched, thereby forming a sacrificial spacer 143 and an outer spacer 145. For example, upper portions of the sacrificial spacer 142 and the outer spacer 144 not covered by the preliminary contact layer BCp may be etched and, as such, heights of the sacrificial spacer 142 and the outer spacer 144 may be lowered. In an embodiment, the etching process may include an anisotropic etching process or an isotropic etching process. An upper lateral side surface of the inner spacer 140 may be exposed by the etching process. Upper surfaces of the sacrificial spacer 143 and the outer spacer 145 may be disposed at a higher level than the upper surface of the preliminary contact layer BCp. However, embodiments of the present inventive concept are not limited to the above-described condition, and, in an embodiment, the upper surfaces of the sacrificial spacer 143 and the outer spacer 145 may be coplanar with the upper surface of the preliminary contact layer BCp. In addition, an upper surface of the second capping layer 134 may be partially etched by the etching process. For example, the upper surface of the second capping layer 134 may be rounded.

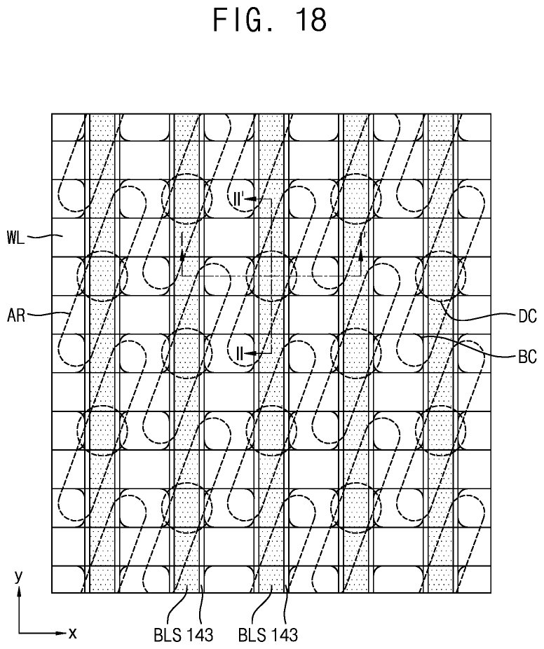

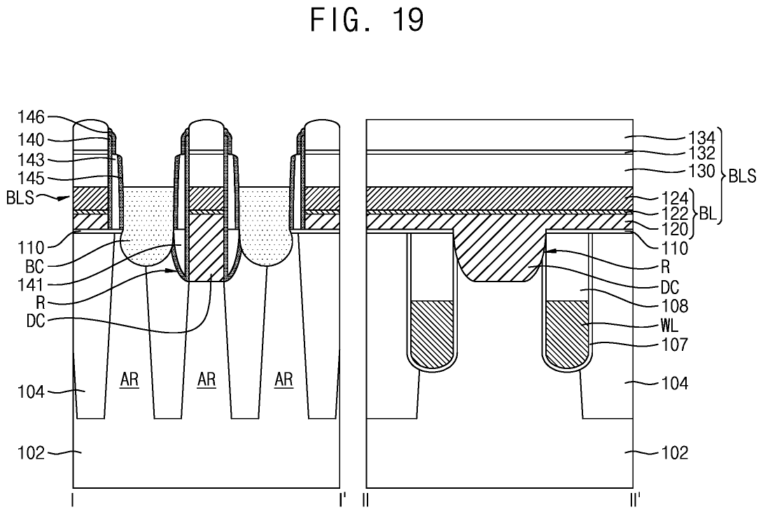

Referring to FIGS. 18 and 19, an upper spacer 146 may be formed on the lateral side surface of the inner spacer 140. In an embodiment, the upper spacer 146 may be formed by conformally depositing an insulating material on the resultant structure of FIG. 17, and then performing an anisotropic etching process such that the second capping layer 134 and the preliminary contact layer BCp are exposed. However, embodiments of the present inventive concept are not limited thereto. The upper spacer 146 may cover an upper portion of the inner spacer 140 not covered by the sacrificial spacer 143. In addition, a lower surface of the upper spacer 146 may directly contact an upper surface of the sacrificial spacer 143. When viewed in a plan view (e.g., in a plane defined in the X and Y directions), the upper spacer 146 may have a ring shape or a frame shape surrounding the buried contact BC. The horizontal width of the upper spacer 146 may be less than the sum of upper widths of the sacrificial spacer 143 and the outer spacer 145. For example, the distance between adjacent ones of upper spacers 146 may be greater than the distance between adjacent ones of outer spacers 145. Accordingly, a landing pad LP, which will be described later, may be formed to be wider. In an embodiment, the upper spacer 146 may include silicon oxide, silicon nitride, silicon oxynitride, or a combination thereof. In an embodiment, the upper spacer 146 may include silicon nitride. However, embodiments of the present inventive concept are not limited thereto.

After formation of the upper spacer 146, an upper portion of the preliminary contact layer BCp may be partially etched and, as such, a buried contact BC may be formed. An upper surface of the buried contact BC may be disposed at a lower level than a level of the upper surface of the sacrificial spacer 143 and a level of an upper surface of the outer spacer 145. A lateral side surface of the outer spacer 145 may be partially exposed. For example, an upper portion of the lateral side surface of the outer spacer 145 may be exposed.

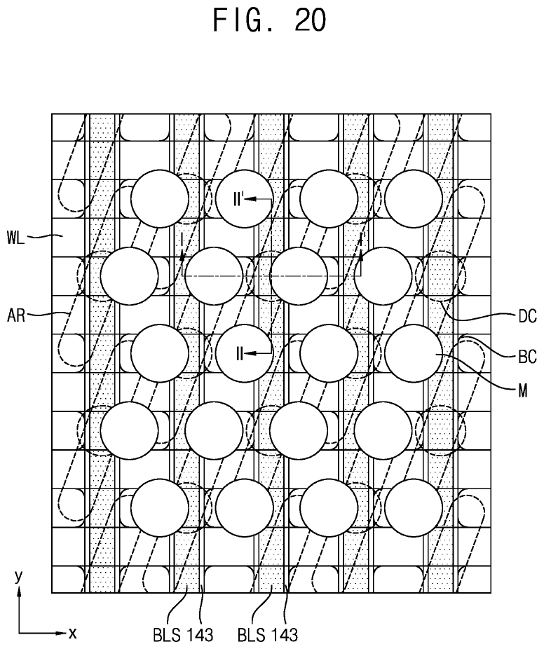

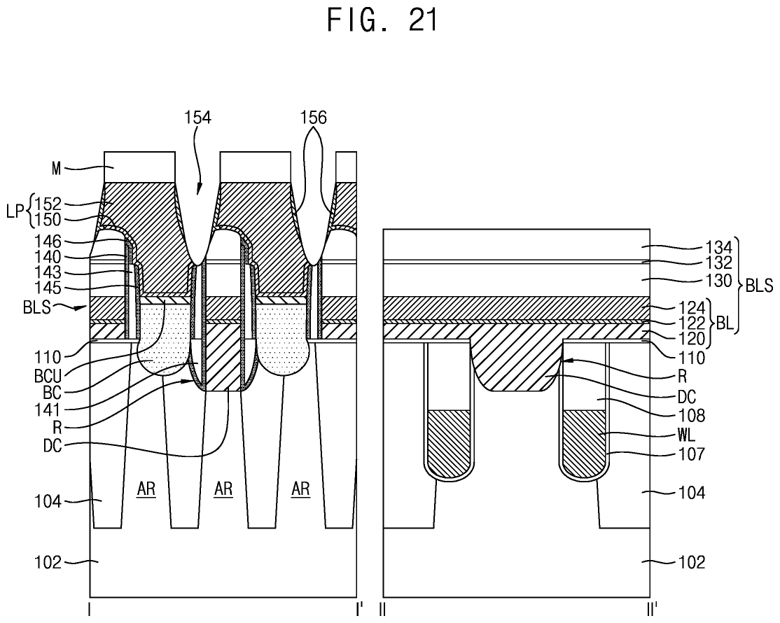

FIG. 21 is a vertical cross-sectional view of FIG. 20. FIG. 22 is an enlarged view of a portion of FIG. 20.

Referring to FIGS. 20 to 22, a barrier pattern 150 and a conductive pattern 152 may be formed. The barrier pattern 150 and the conductive pattern 152 may constitute a landing pad LP. In an embodiment, the formation of the barrier pattern 150 and the conductive pattern 152 may include conformally depositing a barrier material on the resultant structure of FIG. 19, forming a conductive material on the barrier material, and etching the barrier material and the conductive material, thereby forming a pad recess 154.

In an embodiment, the barrier pattern 150 may include metal silicide such as cobalt silicide, nickel silicide and manganese silicide. The conductive pattern 152 may include polysilicon, metal, metal silicide, conductive metal nitride, or a combination thereof. For example, in an embodiment, the conductive pattern 152 may include tungsten.

As shown in the embodiment of FIG. 21, the formation of the pad recess 154 may include forming a hard mask M on the conductive material, etching the conductive material through an etching process using the hard mask M as an etch mask, depositing an insulating material on an etched portion of the conductive material, and further performing an etching process to etch a lower portion of the insulating material. The insulating material not removed may remain at a lateral side wall of the pad recess 154 and, as such, may form an insulating pattern 156. However, embodiments of the present inventive concept are not limited thereto. For example, in an embodiment, the insulating pattern 156 may be omitted. In an embodiment, the insulating pattern 156 may include silicon oxide, silicon nitride, silicon oxynitride, or a combination thereof. For example, the insulating pattern 156 may include silicon nitride. However, embodiments of the present inventive concept are not limited thereto.

The pad recess 154 may partially expose the bit line structure BLS and the spacers. For example, the inner spacer 140 and the sacrificial spacer 143 may be partially exposed. For example, upper portions of the inner spacer 140 and the sacrificial spacer 143 may be exposed. In an embodiment, the outer spacer 145 may also be partially exposed, such as an upper surface of the outer spacer 145. In addition, a portion of the second capping layer 134 may be exposed by the pad recess 154. In the specification, a portion of the inner spacer 140 disposed within the pad recess 154 may be referred to as an inner lower spacer 140L. For example, the inner lower spacer 140L may cover a lateral side surface of the buried spacer 141. A portion of the inner spacer 140 disposed on an upper portion of the buried spacer 141 may be referred to as an inner upper spacer 140U.

In an embodiment, a silicide pattern BCU may be formed on the buried contact BC before formation of the barrier material and the conductive material. The silicide pattern BCU may be formed by forming a metal layer on the buried contact BC, and reacting the metal layer with the buried contact BC through a thermal treatment process. Silicide patterns BCU may be disposed on buried contacts BC, and may directly contact the barrier pattern 150.

In an embodiment, the silicide pattern BCU may include, for example, titanium silicide, cobalt silicide, nickel silicide, tungsten silicide, platinum silicide, or molybdenum silicide. However, embodiments of the present inventive concept are not limited thereto. For example, in an embodiment, a process for forming the silicide pattern BCU may be omitted.

Referring to FIG. 23, the sacrificial spacer 143 may be removed by an isotropic etching process. For example, the sacrificial spacer 143 may be selectively removed by providing an etchant having etch selectivity with respect to the inner spacer 140 and the outer spacer 145 at the pad recess 154. As the sacrificial spacer 143 is removed, a lower air gap AG1 may be formed in a space surrounded by the buried spacer 141, the inner spacer 140 and the outer spacer 145. The first upper spacer 146 and the outer spacer 145 may be exposed by the lower air gap AG1. In an embodiment, when viewed in a cross-sectional view (e.g., in a plane defined in the X and Y directions), the sacrificial spacer 143 disposed at a right side of the bit line structure BLS may also be exposed by the pad recess 154, and may be removed by the etching process and, as such, the lower air gap AG1 may be formed.

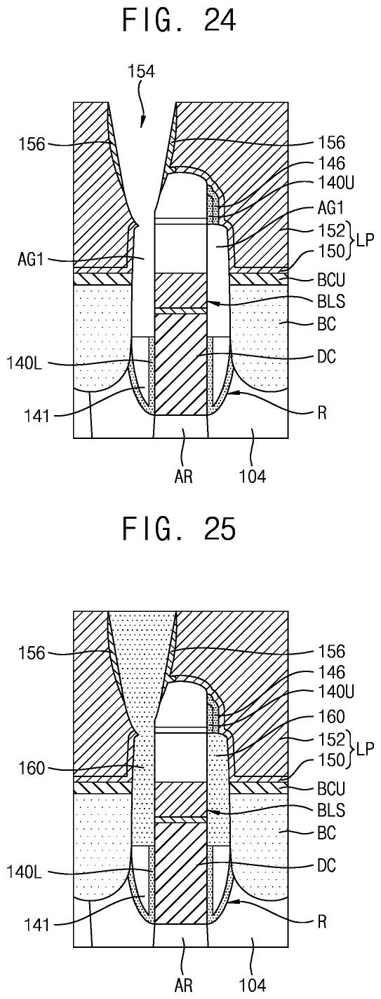

Referring to FIG. 24, the inner upper spacer 140U and the outer spacer 145 exposed by the lower air gap AG1 may be removed. In an embodiment, the inner spacer 140 and the outer spacer 145 may include SiC, SiOC, SiOCN, or a combination thereof, and may be removed by an ashing process. For example, the inner upper spacer 140U and the outer spacer 145 exposed by the lower air gap AG1 may be oxidized by a plasma ashing process. However, embodiments of the present inventive concept are not limited thereto. Thereafter, the oxidized inner upper spacer 140U and the oxidized outer spacer 145 may be selectively removed by a dry etching process or an isotropic etching process. As the inner upper spacer 140U and the outer spacer 145 are removed, the lower air gap AG1 may be enlarged, and may be defined by a space surrounded by the bit line structure BLS, the buried spacer 141, the buried contact BC, the silicide pattern BCU and the landing pad LP. For example, the buried spacer 141 may form a lower limit of the air gap AG. Although the inner upper spacer 140U and the upper spacer 146 are shown as remaining without being removed from a lateral side of the bit line structure BLS opposite to the pad recess 154 when viewed in a cross-sectional view, embodiments of the present inventive concept are not limited thereto. In an embodiment, the inner upper spacer 140U may be completely removed by an ashing process. In an embodiment, when the upper spacer 146 includes SiC, SiOC, SiOCN, or a combination thereof, the upper spacer 146 may also be removed by an ashing process.

As shown in FIG. 24, the lower air gap AG1 may be enlarged as the inner spacer 140 and the outer spacer 145 are removed and, as such, the distance between the bit line structure BLS and the buried contact BC may increase. Accordingly, a parasitic capacitance between the bit line structure BLS and the buried contact BC may be reduced, and the reliability and electrical characteristics of the resultant device may be increased.

Referring to FIG. 25, a sacrificial layer 160 may be formed to fill the pad recess 154 and the lower air gap AG1. The sacrificial layer 160 may directly contact the bit line structure BLS, the buried spacer 141, the buried contact BC, the landing pad LP and the insulating pattern 156. In an embodiment, the sacrificial layer 160 may include polymer or a material which is thermally decomposable. For example, the sacrificial layer 160 may include amorphous silicon. However, embodiments of the present inventive concept are not limited thereto.

Referring to FIG. 26, an upper portion of the sacrificial layer 160 may be partially etched. For example, the upper portion of the sacrificial layer 160 may be removed by an etch-back process. A lateral side surface of the pad recess 154 and the insulating pattern 156 may be exposed by the etching process. An upper surface of the etched sacrificial layer 160 may be disposed at a lower level than an upper surface of the landing pad LP and the upper surface of the bit line structure BLS. The etched sacrificial layer 160 may fill lower portions of the lower air gap AG1 and the pad recess 154.

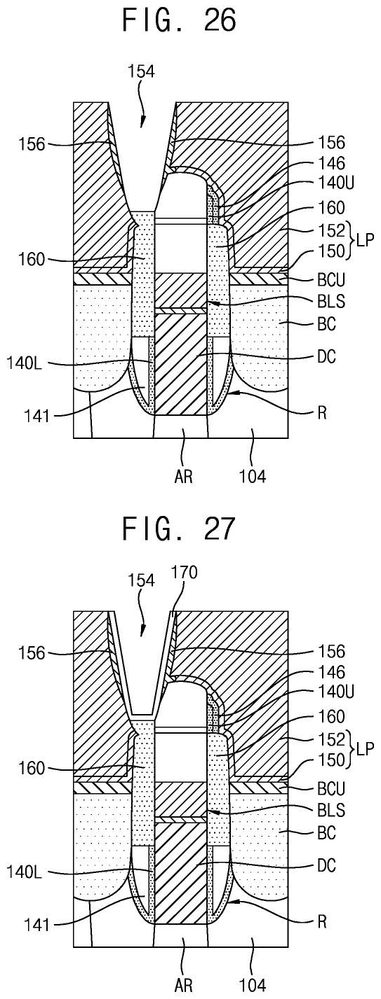

Referring to FIG. 27, a lower insulating layer 170 may be deposited on an inner wall of the pad recess 154. The lower insulating layer 170 may be conformally formed along the inner wall of the pad recess 154, and may directly contact the insulating pattern 156 and the sacrificial layer 160. In an embodiment, the lower insulating layer 170 may be formed by a chemical vapor deposition (CVD) process, an atomic layer deposition (ALD) process, or a physical vapor deposition (PVD) process, and the deposition process may be performed at a temperature that is low enough that the sacrificial layer 160 is not decomposed. The lower insulating layer 170, which is formed by a low-temperature deposition process, may be a porous thin film. In an embodiment, the lower insulating layer 170 may include silicon oxide, silicon nitride, silicon oxynitride, or a combination thereof.

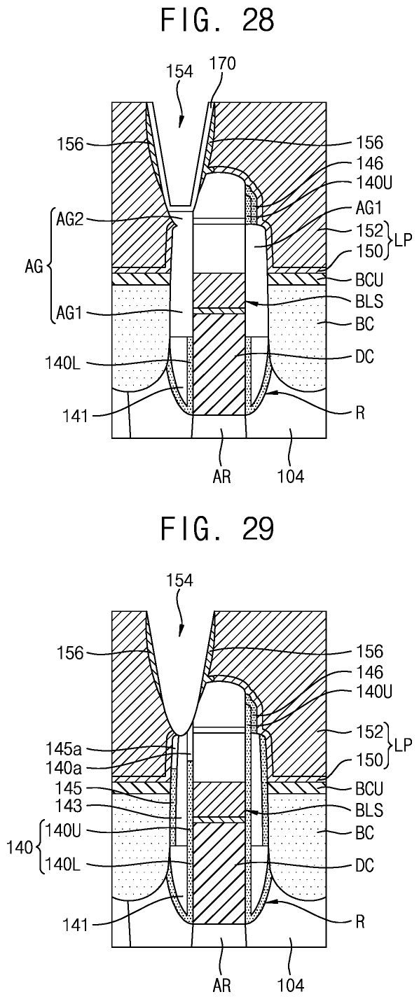

Referring to FIG. 28, the sacrificial layer 160 may be removed, thereby forming a lower air gap AG1 and an upper air gap AG2. In an embodiment, the sacrificial layer 160 may be removed by a thermal decomposition process, and may be discharged through the lower insulating layer 170 which is a porous thin film. The lower air gap AG1 and the upper air gap AG2 may constitute an air gap AG. The lower air gap AG1 may be defined by a space surrounded by the bit line structure BLS, the buried spacer 141, the buried contact BC and the landing pad LP. The upper air gap AG2 may be defined by a space surrounded by the landing pad LP, the lower insulating layer 170 and the bit line structure BLS. The upper air gap AG2 may be disposed on the lower air gap AG1, and may communicate with the lower air gap AG1.

Again referring to FIGS. 1 to 3, an upper insulating layer 172 may be formed on the lower insulating layer 170, to fill the pad recess 154. In an embodiment, an upper surface of the upper insulating layer 172 may be coplanar with the upper surface of the landing pad LP. The lower insulating layer 170 and the upper insulating layer 172 may constitute an insulating structure 174. In an embodiment, the upper insulating layer 172 may include silicon oxide, silicon nitride, silicon oxynitride, or a combination thereof. However, embodiments of the present inventive concept are not limited thereto.

Thereafter, a lower electrode 180, a capacitor dielectric layer 182, an upper electrode 184, and an upper insulating layer 172 may be formed and, as such, a semiconductor device 100 may be formed. The lower electrode 180 may be disposed to correspond to the landing pad LP. For example, the lower electrode 180 may directly contact the upper surface of the landing pad LP, and may be electrically connected to the drain region via the landing pad LP and the buried contact BC. In an embodiment, the lower electrode 180 may have a pillar shape. However, embodiments of the present inventive concept are not limited thereto and the shape of the lower electrode 180 may vary. For example, in an embodiment, the lower electrode 180 may have a cylindrical shape or a hybrid shape of a pillar shape and a cylindrical shape.

The capacitor dielectric layer 182 may be conformally formed along surfaces of the landing pad LP, the insulating structure 174 and the lower electrode 180. The upper electrode 184 may be formed on the capacitor dielectric layer 182. The lower electrode 180, the capacitor dielectric layer 182 and the upper electrode 184 may form a capacitor structure of the semiconductor device 100.

In an embodiment, the lower electrode 180 may include a metal such as Ti, W, Ni, Co or a metal nitride such as TiN, TiSiN, TiAlN, TaN, TaSiN, WN, etc. For example, the lower electrode 180 may include TiN. The capacitor dielectric layer 182 may include a metal oxide such as HfO₂, ZrO₂, Al₂O₃, La₂O₃, Ta₂O₃, and TiO₂, a dielectric material having a perovskite structure such as SrTiO₃(STO), BaTiO₃, PZT and PLZT, or a combination thereof. The upper electrode 184 may include a metal such as Ti, W, Ni and Co or a metal nitride such as TiN, TiSiN, TiAlN, TaN, TaSiN, WN, etc. However, embodiments of the present inventive concept are not limited thereto.

FIGS. 29 to 31 are vertical cross-sectional views illustrating in process order of a method of manufacturing a semiconductor device according to embodiments of the present inventive concept.

In an embodiment, an ashing process may be performed before the performance of the removal process for the sacrificial spacer 143 described with reference to FIG. 23. FIG. 29 shows an inner spacer 140 and an outer spacer 145 for which the above-described method has been performed. Upper portions of the inner spacer 140 and the outer spacer 145 may be oxidized by the ashing process. For example, an inner oxide layer 140a and an outer oxide layer 145a may be formed on an inner upper spacer 140U and the outer spacer 145 which are exposed to the pad recess 154, respectively.

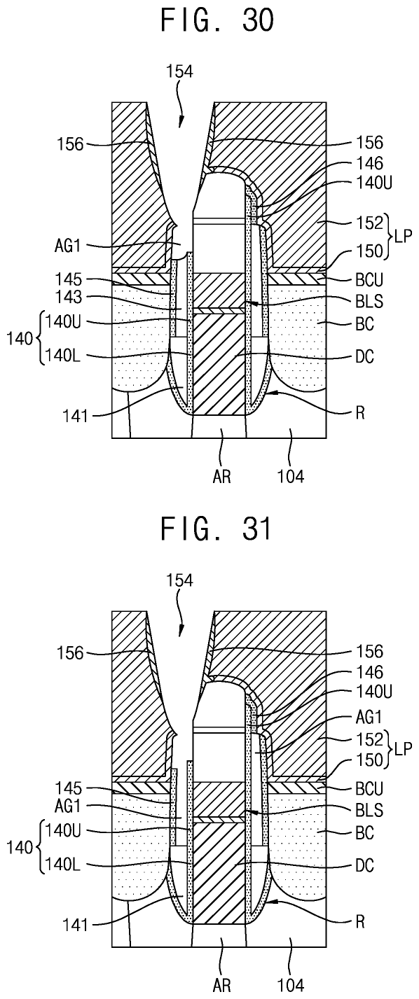

Referring to FIG. 30, oxides may be selectively removed by an isotropic etching process. The inner oxide layer 140a and the outer oxide layer 145a may be removed, and an upper portion of the sacrificial spacer 143 may be partially etched. By the etching process, a lower air gap AG1 may be formed in a space surrounded by the inner upper spacer 140U, the sacrificial spacer 143, the outer spacer 145, a bit line structure BLS and a landing pad LP.

Referring to FIG. 31, the sacrificial spacer 143 may be selectively removed by an isotropic etching process. As shown in FIGS. 29 and 30, it may be possible to enlarge a space, into which an etchant is introduced in an etching process for the sacrificial spacer 143, by oxidizing the inner spacer 140 and the outer spacer 145, thereby forming an oxide layer, and then removing the oxide layer, thereby forming the lower air gap AG1, and, as such, the difficulty of the etching process may decrease. Subsequently, the remaining inner upper spacer 140U and the remaining outer spacer 145 may be removed by an ashing process.

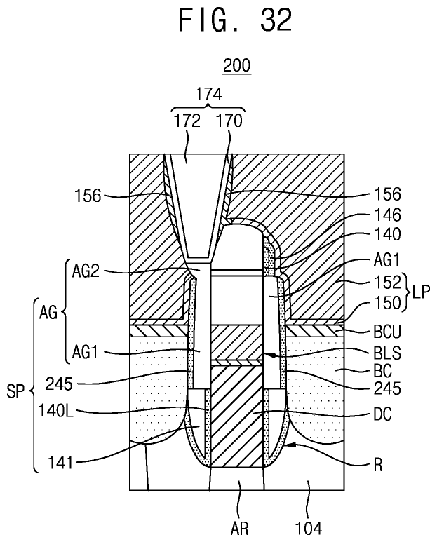

FIGS. 32 to 35 are cross-sectional views of semiconductor devices according to embodiments of the present inventive concept.

Referring to FIG. 32, a spacer structure SP of a semiconductor device 200 may include an outer spacer 245 provided between a buried contact BC and a bit line structure BLS. The outer spacer 245 may constitute a spacer structure SP. In an embodiment, the outer spacer 245 may not be removed by the ashing process described with reference to FIG. 24. For example, in an embodiment, the outer spacer 245 may include silicon nitride. A lower air gap AG1 may be positioned between the outer spacer 245 and the bit line structure BLS. For example, the lower air gap AG1 may be defined by the outer spacer 245, a buried spacer 141 and the bit line structure BLS. The buried contact BC and a landing pad LP, which are partially covered by the outer spacer 245, may not be exposed to the lower air gap AG1. At any vertical level between the buried spacer 141 and an upper air gap AG2, the horizontal distance between the outer spacer 245 and the bit line structure BLS may be equal to the horizontal width of the lower air gap AG1.

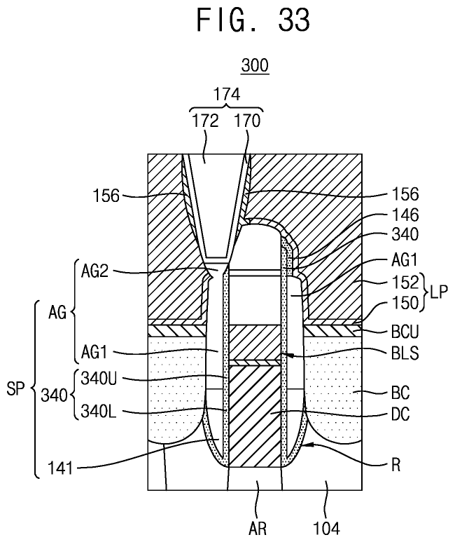

Referring to FIG. 33, a spacer structure SP of a semiconductor device 300 may include an inner spacer 340 provided between a buried contact BC and a bit line structure BLS. The inner spacer 340 may include an inner lower spacer 340L disposed along an inner wall of a contact recess R and a lateral side surface of a direct contact DC, and an inner upper spacer 340U disposed on the inner lower spacer 340L while covering a lateral side surface of the bit line structure BLS. In an embodiment, the inner spacer 340 may not be removed by the ashing process described with reference to FIG. 24. For example, the inner spacer 340 may include silicon nitride. A lower air gap AG1 may be positioned between the buried contact BC and the inner spacer 340. For example, the lower air gap AG1 may be defined by the buried contact BC, a buried spacer 141, and the inner spacer 340. The bit line structure BLS may be covered by the inner spacer 340 and, as such, may not be exposed to the lower air gap AG1. At any vertical level between the buried spacer 141 and an upper air gap AG2, the horizontal distance between the buried contact BC and the inner spacer 340 may be equal to the horizontal width of the lower air gap AG1.

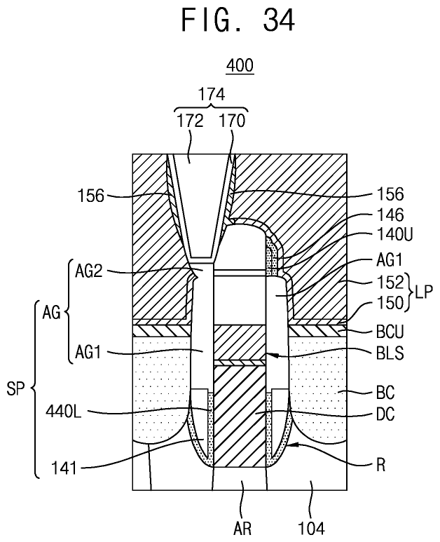

Referring to FIG. 34, a spacer structure SP of a semiconductor device 400 may include an inner lower spacer 440L disposed along an inner wall of a contact recess R and a lateral side surface of a direct contact DC. A buried contact BC and a bit line structure BLS may be exposed to a lower air gap AG1. In an embodiment, an upper surface of the inner lower spacer 440L may be disposed at a lower level than an upper surface of a buried spacer 141. In addition, an upper surface of the inner lower spacer 440L may be concave.

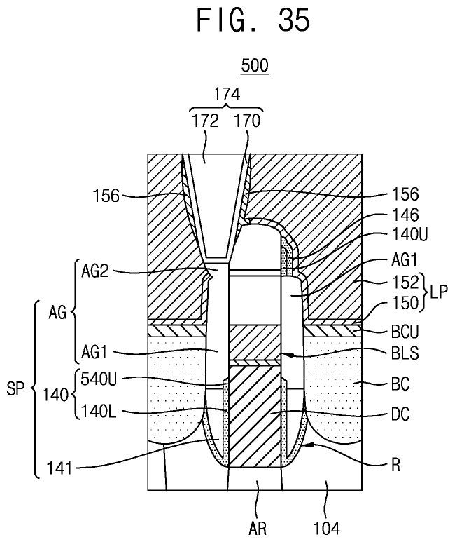

Referring to FIG. 35, a spacer structure SP of a semiconductor device 500 may include an inner upper spacer 540U disposed on an inner lower spacer 140L while partially covering a lateral side surface of a bit line structure BLS. A buried contact BC and the bit line structure BLS may be exposed to a lower air gap AG1. In an embodiment, an upper surface of the inner upper spacer 540U may be disposed at a higher level than an upper surface of a buried spacer 141. In addition, the upper surface of the inner upper spacer 540U may be concave. Although the upper surface of the inner upper spacer 540U is shown as being disposed at a lower level than an upper surface of a direct contact DC, embodiments of the present inventive concept are not limited thereto.

In accordance with embodiments of the present inventive concept, a spacer structure may include an air gap and, as such, parasitic capacitance between a bit line structure and a buried contact may be reduced.

While embodiments of the present inventive concept have been described with reference to the accompanying drawings, it should be understood by those skilled in the art that various modifications may be made without departing from the scope of the present inventive concept and without changing essential features thereof. Therefore, the above-described embodiments should be considered in a descriptive sense only and not for purposes of limitation.

What is claimed is:

1. A semiconductor device comprising:
a substrate including an active region and a contact recess;
a gate electrode disposed in the substrate and extending in a first direction;
a bit line structure intersecting the gate electrode and extending in a second direction intersecting the first direction, the bit line structure including a direct contact disposed in the contact recess;
a buried contact disposed on the substrate and electrically connected to the active region; and
a spacer structure disposed between the bit line structure and the buried contact,
wherein the spacer structure includes a buried spacer disposed on a lateral side surface of the direct contact, and an air gap disposed on the buried spacer,
wherein the air gap exposes a lateral side surface of the bit line structure.

2. The semiconductor device according to claim 1, wherein the air gap further exposes the buried contact.

3. The semiconductor device according to claim 2, wherein, at a first vertical level, a horizontal distance between the buried contact and the bit line structure is equal to a horizontal width of the air gap.

4. The semiconductor device according to claim 1, further comprising:
a landing pad disposed on the buried contact,
wherein the air gap further exposes the landing pad.

5. The semiconductor device according to claim 4, wherein, at a second vertical level, a horizontal distance between the landing pad and the bit line structure is equal to a horizontal width of the air gap.

6. The semiconductor device according to claim 1, wherein:
the spacer structure further includes an outer spacer directly contacting the buried contact; and
the air gap is positioned between the outer spacer and the bit line structure.

7. The semiconductor device according to claim 6, further comprising:
a landing pad disposed on the buried contact,
wherein the outer spacer directly contacts the landing pad.

8. The semiconductor device according to claim 1, wherein the spacer structure further includes an inner lower spacer disposed at a lower portion of the buried spacer and extending along an inner wall of the contact recess and the lateral side surface of the bit line structure.

9. The semiconductor device according to claim 8, wherein an upper surface of the inner lower spacer is coplanar with an upper surface of the buried spacer.

10. The semiconductor device according to claim 8, wherein an upper surface of the inner lower spacer is disposed at a lower level than a level of an upper surface of the buried spacer.

11. The semiconductor device according to claim 8, wherein the spacer structure further includes an inner upper spacer disposed on the inner lower spacer and extending along the lateral side surface of the bit line structure, and an upper surface of the inner upper spacer is disposed at a higher level than an upper surface of the buried spacer.

12. The semiconductor device according to claim 8, wherein the inner lower spacer includes at least one compound selected from SiC, SiOC, and SiOCN.

13. The semiconductor device according to claim 1, wherein a lower limit of the air gap is defined by the buried spacer.

14. A semiconductor device comprising:
a substrate including an active region and a contact recess;
a gate electrode disposed in the substrate and extending in a first direction;
a first bit line structure and a second bit line structure intersecting the gate electrode and extending in a second direction intersecting the first direction, the first bit line structure including a direct contact disposed in the contact recess;
a buried contact electrically connected to the active region and disposed between the first bit line structure and the second bit line structure;
a landing pad disposed on the buried contact;
a first spacer structure disposed between the first bit line structure and the buried contact, the first spacer structure including a buried spacer disposed on a lateral side surface of the direct contact, and a first air gap disposed on the buried spacer; and
a second spacer structure disposed between the second bit line structure and the buried contact,
wherein the second spacer structure includes a second air gap disposed on the substrate,
wherein the first air gap exposes a lateral side surface of at least one of the first bit line structure and the buried contact.

15. The semiconductor device according to claim 14, further comprising:
an insulating structure directly contacting the landing pad and the first bit line structure.

16. The semiconductor device according to claim 15, wherein:
the first air gap includes a first lower air gap, and a first upper air gap disposed on the first lower air gap,
wherein the first lower air gap is defined by the buried contact, the buried spacer, the landing pad and the first bit line structure, and
wherein the first upper air gap is defined by the landing pad, the insulating structure and the first bit line structure.

17. The semiconductor device according to claim 14, wherein the first air gap and the second air gap expose opposite lateral side surfaces of the buried contact.

18. The semiconductor device according to claim 14, wherein the first spacer structure further includes an inner spacer covering the lateral side surface of the first bit line structure.

19. A semiconductor device comprising:
a substrate including an active region and a contact recess;
a gate electrode disposed in the substrate and extending in a first direction;
a first bit line structure and a second bit line structure intersecting the gate electrode and extending in a second direction intersecting the first direction, the first bit line structure including a direct contact disposed in the contact recess;
a buried contact electrically connected to the active region and disposed between the first bit line structure and the second bit line structure;
a landing pad disposed on the buried contact;
an insulating structure directly contacting the landing pad and the first bit line structure;
a first spacer structure disposed between the first bit line structure and the buried contact, the first spacer structure including a buried spacer disposed on a lateral side surface of the direct contact, and a first air gap disposed on the buried spacer; and
a second spacer structure disposed between the second bit line structure and the buried contact, the second spacer structure including a second air gap on the substrate; and
a capacitor structure disposed on the landing pad,
wherein the first air gap exposes the insulating structure, the first bit line structure and the buried contact, and the second air gap exposes a lateral side surface of the second bit line structure.

20. The semiconductor device according to claim 19, wherein:
the first air gap includes a first lower air gap, and a first upper air gap disposed on the first lower air gap;
the first lower air gap is defined by the buried contact, the buried spacer, the landing pad and the first bit line structure; and
the first upper air gap is defined by the landing pad, the insulating structure and the first bit line structure.
